(19) United States
(12) Patent Application Publication
(10) Pub. No.: US 2015/0090322 A1
(43) Pub. Date: Apr. 2, 2015

(54) SOLAR CELL APPARATUS AND METHOD OF FABRICATING THE SAME

(71) Applicant: LG INNOTEK CO., LTD., Seoul (KR)

(72) Inventor: Jin Woo Lee, Seoul (KR)

(21) Appl. No.: 14/366,584

(22) PCT Filed: Dec. 17, 2012
(86) PCT No.: PCT/KR2012/010995

§ 371 Date: Jun. 18, 2014

(30) Foreign Application Priority Data
Dec. 18, 2011 (KR) 10-2011-0136918

(51) Int. Cl. H01L 31/065; H01L 31/032; H01L 31/0224

(52) U.S. Cl. CPC H01L 31/065; H01L 31/022425; H01L 31/0322
USPC 136/255; 438/87

(57) ABSTRACT

Disclosed are a solar cell apparatus and a method of fabricating the same. The solar cell apparatus includes a substrate; a back electrode layer on the substrate; a light absorbing layer on the back electrode layer; and a front electrode layer on the light absorbing layer, wherein the light absorbing layer includes: a first region having a bandgap energy which is gradually increased in a direction of the front electrode; a second region on the first region, the second region having a bandgap energy which is gradually decreased in a direction of the front electrode layer; a third region on the second region, the third region having a bandgap energy which is gradually increased in a direction of the front electrode layer; and a fourth region on the first region, the fourth region having a bandgap energy which is gradually decreased in a direction of the front electrode layer.

### TECHNICAL FIELD

The embodiment relates to a solar cell apparatus and a method of fabricating the same.

### BACKGROUND ART

A method of fabricating a solar cell for solar light power generation is as follows. First, after preparing a substrate, a back electrode layer is formed on the substrate. Thereafter, a light absorbing layer, a buffer layer, and a high resistance buffer layer are sequentially formed on the back electrode layer. Various schemes, such as a scheme of forming a Cu(In,Ga)Se₂ (CIGS) based-light absorbing layer by simultaneously or separately evaporating Cu, In, Ga, and Se and a scheme of performing a selenization process after a metallic precursor film has been formed, have been extensively used in order to form the light absorbing layer. The energy bandgap of the light absorbing layer is in the range of about 1 eV to 1.8 eV.

Then, a buffer layer including cadmium sulfide (CdS) is formed on the light absorbing layer through a sputtering process. The energy bandgap of the buffer layer may be in the range of about 2.2 eV to 2.4 eV. After that, a high resistance buffer layer including zinc oxide (ZnO) is formed on the buffer layer through the sputtering process. The energy bandgap of the high resistance buffer layer is in the range of about 3.1 eV to about 3.3 eV.

Then, a transparent conductive material is laminated on the high resistance buffer layer, and a transparent electrode layer is formed on the high resistance buffer layer. A material constituting the transparent electrode layer may include aluminum doped zinc oxide (AZO). The energy bandgap of the transparent electrode layer may be in the range of about 3.1 eV to about 3.3 eV.

In such a solar cell apparatus, various studies for improving photoelectric conversion efficiency by controlling bandgap energy in the light absorbing layer have been performed.

As described above, in order to convert the solar light into electrical energy, various solar cell apparatuses have been fabricated and used. One of the solar cell apparatuses is disclosed in Korean Unexamined Patent Publication No. 10-2008-0088744.

### DISCLOSURE OF INVENTION

### Technical Problem

The embodiment provides a solar cell apparatus which can reduce recombination between electrons and holes to improve photoelectric conversion efficiency, and a method of fabricating the same.

### Solution to Problem

A solar cell apparatus according to the embodiment includes a substrate; a back electrode layer on the substrate; a light absorbing layer on the back electrode layer; and a front electrode layer on the light absorbing layer, wherein the back electrode layer includes: a first region having a bandgap energy which is gradually increased in a direction of the front electrode; a second region on the first region, the second region having a bandgap energy which is gradually decreased in a direction of the front electrode layer; a third region on the second region, the third region having a bandgap energy which is gradually increased in a direction of the front electrode layer; and a fourth region on the first region, the fourth region having a bandgap energy which is gradually decreased in a direction of the front electrode layer.

A solar cell apparatus according to the embodiment includes a substrate; a back electrode layer on the substrate; a light absorbing layer on the back electrode layer; and a front electrode layer on the back electrode layer, wherein the back electrode layer includes: a first region having a conduction band which is gradually increased in a direction of the front electrode; a second region on the first region, the second region having a conduction band which is gradually decreased in a direction of the front electrode; a third region on the second region, the third region having a conduction band which is gradually increased in a direction of the front electrode; and a fourth region on the third region, the fourth region having a conduction band which is gradually decreased in a direction of the front electrode.

A method of fabricating a solar cell apparatus according to the embodiment includes forming a back electrode layer on a substrate; forming a light absorbing layer on the back electrode layer; and forming a front electrode layer on the light absorbing layer, wherein the back electrode layer comprises: a first region having a bandgap energy which is gradually increased in a direction of the front electrode; a second region on the first region, the second region having a bandgap energy which is gradually decreased in a direction of the front electrode layer; a third region on the second region, the third region having a bandgap energy which is gradually increased in a direction of the front electrode layer; and a fourth region on the first region, the fourth region having a bandgap energy which is gradually decreased in a direction of the front electrode layer.

### Advantageous Effects of Invention

According to the embodiment, the solar cell apparatus can control the bandgap energy of the light absorbing layer in a harmonic shape by using the first to fourth regions.

That is, since the bandgap energy of the first to fourth regions, specifically, the conduction band has the harmonic shape, the electrons trapped at the minimum point are tunneled by Poole-Frenkle effect in the field. Thus, the solar cell apparatus according to the embodiment can prevent the recombination of electrons.

Therefore, the solar cell apparatus according to the embodiment may have improved photoelectric conversion efficiency.

### BRIEF DESCRIPTION OF DRAWINGS

FIG. 1 is a sectional view showing a solar cell apparatus according to the embodiment;

FIG. 2 is an enlarged sectional view showing a part A of FIG. 1;

FIG. 3 is a view showing a bandgap energy of a light absorbing layer;

FIG. 4 is a view showing a content of a bandgap control material in a light absorbing layer; and

FIGS. 5 to 8 are views showing the method of fabricating the solar cell apparatus according to the embodiment.

### BEST MODE FOR CARRYING OUT THE INVENTION

In the description of the embodiments, it will be understood that, when a substrate, a film, a layer, or an electrode is referred to as being on or under another substrate, layer, film, or electrode, it can be directly or indirectly on the other substrate, film, layer, or electrode, or one or more intervening layers may also be present. Such a position of the element described with reference to the drawings. The thickness and size of each element shown in the drawings may be exaggerated, omitted or schematically drawn for the purpose of convenience or clarity. In addition, the size of elements does not utterly reflect an actual size.

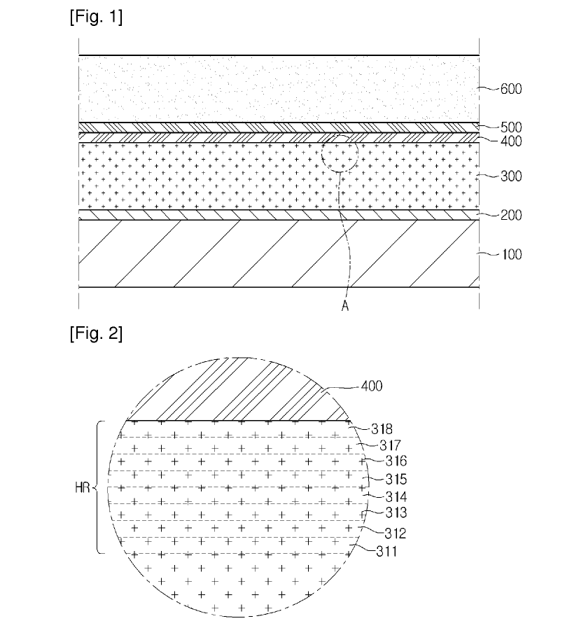

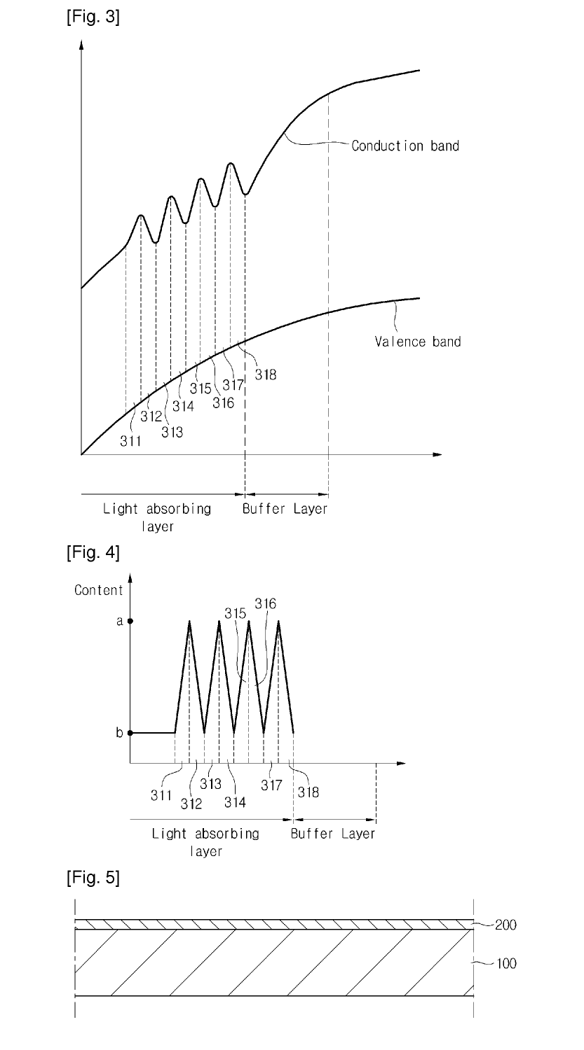

FIG. 1 is a sectional view showing a solar cell apparatus according to the embodiment. FIG. 2 is an enlarged sectional view showing a part A of FIG. 1. FIG. 3 is a view showing a bandgap energy of a light absorbing layer. FIG. 4 is a view showing a content of a bandgap control material in a light absorbing layer.

Referring to FIGS. 1 to 4, the solar cell according to the embodiment includes a support substrate 100, a back electrode layer 200, a light absorbing layer 300, a buffer layer 400, a high resistance buffer layer 500, and a front electrode layer 600.

The support substrate 100 has a plate shape, and supports the back electrode layer 200, the light absorbing layer 300, the buffer layer 400, the high resistance buffer layer 500, and the front electrode layer 600.

The support substrate 100 may include an insulator. The support substrate 100 may be a glass substrate, a plastic substrate or a metal substrate. In more detail, the support substrate 100 may be a soda lime glass substrate. The support substrate 100 may be transparent. The support substrate 100 may be flexible or rigid.

The back electrode layer 200 is provided on the support substrate 100. The back electrode layer 200 is a conductive layer. For example, a material used for the back electrode layer 200 may include metal such as molybdenum (Mo).

Further, the back electrode layer 200 may include at least two layers. In this case, at least two layers may be formed by using the same metal or different metals.

The light absorbing layer 300 is provided on the back electrode layer 200. The light absorbing layer 300 may include group I-III-VI compounds. For instance, the light absorbing layer 300 may include the Cu(In,Ga)Se₂ (CIGS) crystal structure, the Cu(In)Se₂ crystal structure, or the Cu(Ga)Se₂ crystal structure.

The energy bandgap of the light absorbing layer 300 may be in the range of about 1 eV to 1.8 eV.

The light absorbing layer 300 includes a harmonic region HR. The harmonic region HR may be formed in an upper portion of the light absorbing layer 300. That is, the harmonic region HR may be adjacent to the front electrode layer 600. In more detail, the harmonic region HR may be adjacent to the buffer layer 400.

As shown in FIG. 3, the harmonic region HR may have a bandgap energy of a harmonic shape. That is, the bandgap energy may be gradually increased and decreased repeatedly in the direction of the front electrode layer 600. In more detail, the bandgap energy of the harmonic region HR is gradually increased and decreased repeatedly in the direction of the front electrode layer 600 about 4 times to about 10 times.

In more detail, the harmonic region HR may have a conduction band of a harmonic shape. That is, the conduction band of the harmonic region HR is gradually increased and decreased repeatedly in the direction of the front electrode layer 600. In more detail, the conduction band of the harmonic region HR is gradually increased and decreased repeatedly in the direction of the front electrode layer 600 about 4 times to about 10 times.

The amplitude of the bandgap energy in the harmonic region HR may be in the range of about 0.1 eV to about 0.6 eV. That is, when the bandgap energy of the harmonic region HR is decreased to a lower point and then, increased to an upper point, the difference between the lower point and the upper point of the bandgap energy may be in the range of about 0.1 eV to about 0.6 eV. In more detail, the amplitude of the conduction band in the harmonic region HR may be in the range of about 0.1 eV to about 0.6 eV. In more detail, the difference between the lower point and the upper point of the conduction band in the harmonic region HR may be in the range of about 0.1 eV to about 0.6 eV.

A thickness of the harmonic region HR may be in the range of about 0.4 to about 0.6. The harmonic region HR may include first to eighth regions 311 to 318.

As shown in FIGS. 2 and 3, the first region 311 may be defined at a middle portion of the light absorbing layer 300. The bandgap energy of the first region 311 may be gradually increased in the direction of the front electrode layer 600. That is, the bandgap energy of the first region 311 may be gradually increased in the direction of the buffer layer 400.

Further, the conduction band of the first region 311 may be gradually increased in the direction of the front electrode layer 600. That is, the conduction band of the first region 311 may be gradually increased in the direction of the buffer layer 400.

The second region 312 is defined on the first region 311. The second region 312 is adjacent to the first region 311. The second region 312 may be directly adjacent to the first region 311. The bandgap energy of the second region 312 may be gradually decreased in the direction of the front electrode layer 600. That is, the bandgap energy of the second region 312 may be gradually decreased in the direction of the buffer layer 400.

The conduction band of the second region 312 may be gradually decreased in the direction of the front electrode layer 600. That is, the conduction band of the second region 312 may be gradually decreased in the direction of the buffer layer 400.

The third region 313 is disposed on the second region 312. The third region 313 is adjacent to the second region 312. The third region 313 may be defined to be directly adjacent to the second region 312. The bandgap energy of the third region 313 may be gradually increased in the direction of the front electrode layer 600. That is, the bandgap energy of the third region 313 may be gradually increased in the direction of the buffer layer 400.

Further, the conduction band of the third region 313 may be gradually increased in the direction of the front electrode layer 600. That is, the conduction band of the third region 313 may be gradually increased in the direction of the buffer layer 400.

The fourth region 314 is disposed on the third region 313. The fourth region 314 is adjacent to the third region 313. The fourth region 314 may be defined to be directly adjacent to the third region 313. The bandgap energy of the fourth region 314 may be gradually decreased in the direction of the front electrode layer 600. That is, the bandgap energy of the fourth region 314 may be gradually decreased in the direction of the buffer layer 400.

Further, the conduction band of the fourth region 314 may be gradually decreased in the direction of the front electrode layer 600. That is, the conduction band of the fourth region 314 may be gradually decreased in the direction of the buffer layer 400.

The fifth region 315 is disposed on the fourth region 314. The fifth region 315 is adjacent to the fourth region 314. The fifth region 315 may be defined to be directly adjacent to the fourth region 314. The bandgap energy of the fifth region 315 may be gradually increased in the direction of the front electrode layer 600. That is, the bandgap energy of the fifth region 315 may be gradually increased in the direction of the buffer layer 400.

Further, the conduction band of the fifth region 315 may be gradually increased in the direction of the front electrode layer 600. That is, the conduction band of the fifth region 315 may be gradually increased in the direction of the buffer layer 400.

The sixth region 316 is disposed on the fifth region 315. The sixth region 316 is adjacent to the fifth region 315. The sixth region 316 may be defined to be directly adjacent to the fifth region 315. The bandgap energy of the sixth region 316 may be gradually decreased in the direction of the front electrode layer 600. That is, the bandgap energy of the sixth region 316 may be gradually decreased in the direction of the buffer layer 400.

Further, the conduction band of the sixth region 316 may be gradually decreased in the direction of the front electrode layer 600. That is, the conduction band of the sixth region 316 may be gradually decreased in the direction of the buffer layer 400.

The seventh region 317 is disposed on the sixth region 316. The seventh region 317 is adjacent to the sixth region 316. The seventh region 317 may be defined to be directly adjacent to the sixth region 316. The bandgap energy of the seventh region 317 may be gradually increased in the direction of the front electrode layer 600. That is, the bandgap energy of the seventh region 317 may be gradually increased in the direction of the buffer layer 400.

Further, the conduction band of the seventh region 317 may be gradually increased in the direction of the front electrode layer 600. That is, the conduction band of the seventh region 317 may be gradually increased in the direction of the buffer layer 400.

The eighth region 318 is disposed on the seventh region 317. The eighth region 318 may be defined on the uppermost portion of the light absorbing layer 300. The eighth region 318 is adjacent to the seventh region 317. The eighth region 318 may be defined to be directly adjacent to the seventh region 317. The bandgap energy of the eighth region 318 may be gradually decreased in the direction of the front electrode layer 600. That is, the bandgap energy of the eighth region 318 may be gradually decreased in the direction of the buffer layer 400.

Further, the conduction band of the eighth region 318 may be gradually decreased in the direction of the front electrode layer 600. That is, the conduction band of the eighth region 318 may be gradually decreased in the direction of the buffer layer 400.

In addition, as shown in FIG. 4, the bandgap energies, that is, the conduction bands in the first to eighth regions 311 to 318 may be controlled by the content of a bandgap control material. In more detail, the conduction bands may be controlled by the content of the bandgap control material. In more detail, when the content of the bandgap control material is increased in the first to eighth regions 311 to 318, the bandgap energies may be gradually increased. Further, when the content of the bandgap control material is decreased in the first to eighth regions 311 to 318, the bandgap energies may be gradually decreased.

To the contrary, when the content of the bandgap control material is increased in the first to eighth regions 311 to 318, the bandgap energies may be gradually decreased. In addition, when the content of the bandgap control material is decreased in the first to eighth regions 311 to 318, the bandgap energies may be gradually increased.

The bandgap control material may include gallium (Ga), silver (Ag), sulfur (S), or aluminum (Al).

For example, when the bandgap control material is gallium, the first to eighth regions 311 to 318 may include a semiconductor compound which is expressed as following Chemistry Figure 1:

ChemistryFigure 1

Cu_{Y}(In_{1-X},Ga_{X})Se_{Z} [Chem.1]

wherein Y, Z and X are 0.9<Y<1.1, 1.8<Z<2.2, and 0≦X≦0.4.

Further, X may be gradually increased in the direction of the front electrode layer 600 in the first, third, fifth and seventh regions 311, 313, 315 and 317. In more detail, X may be gradually increased from 0 to 0.4 in the direction of the front electrode layer 600 in the first, third, fifth and seventh regions 311, 313, 315 and 317.

In addition, X may be gradually decreased in the direction of the front electrode layer 600 in the second, fourth, sixth and eighth regions 312, 314, 316 and 318. In more detail, X may be gradually decreased from 0.4 to 0 in the direction of the front electrode layer 600 in the second, fourth, sixth and eighth regions 312, 314, 316 and 318.

For example, when the bandgap control material is silver, the first to eighth regions 311 to 318 may include a semiconductor compound which is expressed as following Chemistry Figure 2:

ChemistryFigure 2

(Cu_{1-Y},Ag_{Y})(In,Ga)_{X}Se_{Z} [Chem.2]

wherein X, Y and Z are 0.9<X<1.1, 1.8<Z<2.2, and 0≦Y≦0.5.

Further, Y may be gradually increased in the direction of the front electrode layer 600 in the first, third, fifth and seventh regions 311, 313, 315 and 317.

In addition, Y may be gradually decreased in the direction of the front electrode layer 600 in the second, fourth, sixth and eighth regions 312, 314, 316 and 318.

For example, when the bandgap control material is aluminum, the first to eighth regions 311 to 318 may include a semiconductor compound which is expressed as following Chemistry Figure 3:

ChemistryFigure 3

Cu_{Y}((In,Ga)_{1-X},Al_{X})Se_{Z} [Chem.3]

wherein Y, Z and X are 0.9<Y<1.1, 1.8<Z<2.2, and 0≦X≦0.5.

Further, X may be gradually increased in the direction of the front electrode layer 600 in the first, third, fifth and seventh regions 311, 313, 315 and 317.

In addition, X may be gradually decreased in the direction of the front electrode layer 600 in the second, fourth, sixth and eighth regions 312, 314, 316 and 318.

For example, when the bandgap control material is sulfur, the first to eighth regions 311 to 318 may include a semiconductor compound which is expressed as following chemical formula 4:

ChemistryFigure 4

Cu_{Y}(In,Ga)_{X}(Se_{1-Z},S_{Z})₂ [Chem.4]

wherein Y, X and Z are 0.9<Y<1.1, 0.9<X<1.1, and 0≦Z≦0.5.

Further, Z may be gradually increased in the direction of the front electrode layer 600 in the first, third, fifth and seventh regions 311, 313, 315 and 317.

In addition, Z may be gradually decreased in the direction of the front electrode layer 600 in the second, fourth, sixth and eighth regions 312, 314, 316 and 318.

The first to eighth regions 311 to 318 may have thicknesses in the range of about 20 nm to 40 nm, respectively.

The buffer layer 400 is provided on the light absorbing layer 300. In more detail, the buffer layer 400 may is directly disposed on the eighth region 318. The buffer layer 400 makes direct contact with the light absorbing layer 300. The buffer layer 400 include cadmium sulfide (CdS). The buffer layer 400 may have an energy bandgap in the range of about 1.9 eV to about 2.3 eV.

The high resistance buffer layer 500 may be provided on the buffer layer 400. The high resistance buffer layer 500 includes zinc oxide (i-ZnO) which is not doped with impurities. The energy bandgap of the high resistance buffer layer 500 may be in the range of about 3.1 eV to about 3.3 eV.

The front electrode layer 600 is provided on the light absorbing layer 300. In more detail, the front electrode layer 600 is provided on the high resistance buffer layer 500.

The front electrode layer 600 is provided on the high resistance buffer layer 500. The front electrode layer 600 is transparent. For example, a material used for the front electrode layer 600 may include an Al doped zinc oxide (AZO), an indium zinc oxide (IZO), or an indium tin oxide (ITO).

A thickness of the front electrode layer 600 may be in the range of about 500 to about 1.5. When the front electrode layer 600 is formed of aluminum doped zinc oxide (AZO), the aluminum (Al) may be doped at the amount of about 2.5 wt % to about 3.5 wt %. The front electrode layer 600 is a conductive layer.

As described above, the solar cell apparatus according to the embodiment may control the bandgap energy of the light absorbing layer 300 by using the first to eighth regions 311 to 318, such that the bandgap energy has the harmonic shape.

Since the bandgap energy, especially, the conduction band in the first to eighth regions 311 to 318 has the harmonic shape, electrons, which are trapped at the minimum point of the conduction band, are tunneled by the Poole-Frenkle effect. Thus, the solar cell apparatus according to the embodiment may prevent recombination of electrons.

Therefore, the solar cell apparatus according to the embodiment may have improved photoelectric conversion efficiency.

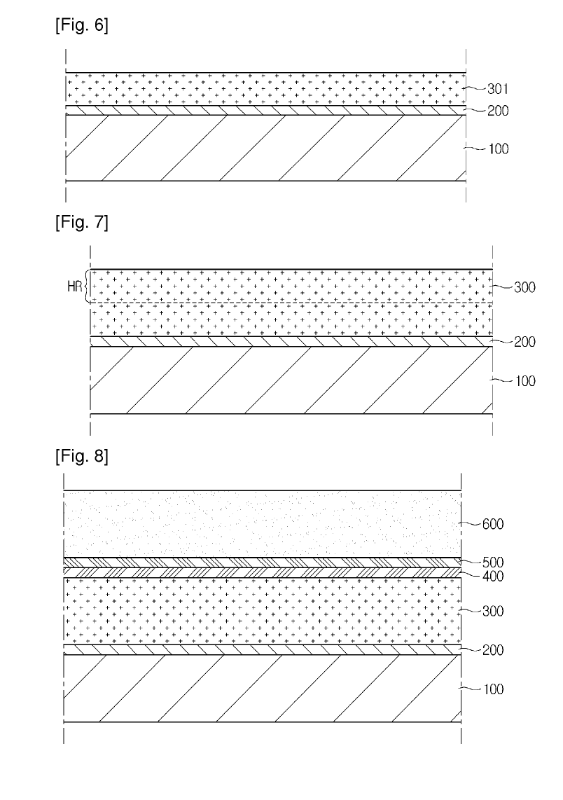

FIGS. 5 to 8 are views showing the method of fabricating the solar cell apparatus according to the embodiment. The present fabricating method will be described with reference to the above-described solar cell. The above description about the solar cell will be essentially incorporated herein by reference.

Referring to FIG. 5, a metal such as molybdenum is deposited on the support substrate 100 through a sputtering process to form the back electrode layer 200. The back electrode layer 200 may be formed by twice performing a process in different conditions.

An additional layer such as a diffusion barrier layer may be interposed between the support substrate 100 and the back electrode layer 200.

Referring to FIG. 3, the lower light absorbing layer 300 is formed on the back electrode layer 200.

The lower light absorbing layer 300 may be formed through a sputtering process or an evaporation process.

For example, various schemes, such as a scheme of forming a Cu(In,Ga)Se₂ (CIGS) based-light absorbing layer 300 by simultaneously or separately evaporating Cu, In, Ga, and Se and a scheme of performing a selenization process after a metallic precursor film has been formed, have been extensively used in order to form the lower light absorbing layer 300.

Regarding the details of the selenization process after the formation of the metallic precursor layer, the metallic precursor layer is formed on the back electrode layer 200 through a sputtering process employing a Cu target, an In target, or a Ga target.

Thereafter, the metallic precursor layer is subject to the selenization process so that the Cu (In, Ga) Seₑ (GIGS) based light absorbing layer 300 is formed.

In addition, the sputtering process employing the Cu target, the In target, and the Ga target and the selenization process may be simultaneously performed.

Further, a CIS or a CIG based light absorbing layer 300 may be formed through the sputtering process employing only Cu and In targets or Cu and Ga targets and the selenization process.

Referring to FIG. 7, the harmonic region HR is formed at an upper portion of the lower light absorbing layer 300. While the group I-III-VI semiconductor compounds are being deposited on the lower light absorbing layer 300, the content of the bandgap control material in the group I-III-VI semiconductor compounds may be controlled. Thus, the bandgap energy in the harmonic region HR may be controlled. In more detail, the conduction band in the harmonic region HR may have a harmonic structure.

In more detail, in order to form the harmonic region HR, group I, III and VI elements are provided on the back electrode layer 200. In more detail, the group I, III and VI elements are provided on the top surface of the lower light absorbing layer 300. At the same time, the bandgap energy control material is provided as well. At this time, the amount of the bandgap energy control material is controlled, so that the bandgap energy of the harmonic region HR may be controlled for each region.

The process temperature in forming the harmonic region HR may be less than that of the process of forming the lower light absorbing layer 300. The lower light absorbing layer 300 may be formed at the temperature in the range of about 500 to about 600, the harmonic region HR may be formed at the temperature in the range of 400 to about 460.

In detail, while the group I, III and VI elements are being provided on the lower light absorbing layer 300, the bandgap energy control material may be simultaneously provided. At this time, a rate of supplying the bandgap energy control material may be gradually increased as the first region 311 is formed.

Then, after the first region 311 has been formed, the group I, III and VI elements are supplied to the first region 311. At the same time, as the second region 312 is formed, the rate of supplying the bandgap energy control material may be gradually decreased.

Then, after the second region 312 has been formed, the group I, III and VI elements are supplied to the second region 312. At the same time, as the third region 313 is formed, the rate of supplying the bandgap energy control material may be gradually increased.

Then, after the third region 313 has been formed, the group I, III and VI elements are supplied to the third region 313. At the same time, as the fourth region 314 is formed, the rate of supplying the bandgap energy control material may be gradually decreased

Then, after the fourth region 314 has been formed, the group I, III and VI elements are supplied to the fourth region 314. At the same time, as the fifth region 315 is formed, the rate of supplying the bandgap energy control material may be gradually increased.

Then, after the fifth region 315 has been formed, the group I, III and VI elements are supplied to the fifth region 315. At the same time, as the sixth region 316 is formed, the rate of supplying the bandgap energy control material may be gradually decreased.

Then, after the sixth region 316 has been formed, the group I, III and VI elements are supplied to the sixth region 316. At the same time, as the seventh region 317 is formed, the rate of supplying the bandgap energy control material may be gradually increased.

Then, after the seventh region 317 is formed, as the eighth region 318 is formed while supplying the group I, III and VI elements on the seventh region 317, the rate of supplying the bandgap energy control material may be decreased simultaneously and gradually. Then, after the seventh region 317 has been formed, the group I, III and VI elements are supplied to the seventh region 317. At the same time, as the eighth region 318 is formed, the rate of supplying the bandgap energy control material may be gradually decreased.

When the bandgap energy control material is deposited through a sputtering process, the rate of supplying the bandgap energy control material may be controlled by a power applied to a sputtering target.

When the bandgap energy control material is deposited through an evaporation process, the rate of supplying the bandgap energy control material may be controlled by adjusting an area of an inlet through which the bandgap energy control material is output.

Thus, the harmonic region HR may control the bandgap energy, specifically, conduction band in the harmonic shape.

Referring to FIG. 8, the buffer layer 400 and the high resistance buffer layer 500 are formed on the light absorbing layer 300.

The buffer layer 400 may be formed through a CBD (Chemical Bath Deposition) process. For example, after the light absorbing layer 300 has been formed, the light absorbing layer 300 is immersed into a solution including materials used to form cadmium sulfide (CdS), and the buffer layer 400 including CdS is formed on the light absorbing layer 300.

Thereafter, zinc oxide is deposited on the buffer layer 400 through a sputtering process, thereby forming the high resistance buffer layer 500.

Then, a front electrode layer 600 is formed on the high resistance buffer layer 500. A transparent conductive material is stacked on the high resistance buffer layer 500 to form the front electrode layer 600. For example, the transparent conductive material includes aluminum (Al) doped zinc oxide (AZO), an indium zinc oxide (IZO), or an indium tin oxide (ITO).

As described above, the light absorbing layer 300 having the bandgap energy of the harmonic structure may be easily formed.

Any reference in this specification to one embodiment, an embodiment, example embodiment, etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell apparatus comprising:
a substrate;
a back electrode layer on the substrate;
a light absorbing layer on the back electrode layer; and
a front electrode layer on the light absorbing layer,
wherein the light absorbing layer comprises:
a first region having a bandgap energy which is gradually increased in a direction of the front electrode;
a second region on the first region, the second region having a bandgap energy which is gradually decreased in a direction of the front electrode layer;
a third region on the second region, the third region having a bandgap energy which is gradually increased in a direction of the front electrode layer; and
a fourth region on the first region, the fourth region having a bandgap energy which is gradually decreased in a direction of the front electrode layer.

2. The solar cell apparatus of claim 1, wherein the light absorbing layer comprises:
a fifth region on the fourth region, the fifth region having a bandgap energy which is gradually increased in a direction of the front electrode layer; and
a sixth region on the fifth region, the sixth region having a bandgap energy which is gradually decreased in a direction of the front electrode layer.

3. The solar cell apparatus of claim 2, wherein the light absorbing layer comprises:
a seventh region on the sixth region, the seventh region having a bandgap energy which is gradually increased in a direction of the front electrode layer; and
an eighth region on the seventh region, the eighth region having a bandgap energy which is gradually decreased in a direction of the front electrode layer.

4. The solar cell apparatus of claim 3, wherein the light absorbing layer comprises:
a ninth region on the eighth region, the ninth region having a bandgap energy which is gradually increased in a direction of the front electrode layer; and
a tenth region on the ninth region, the tenth region having a bandgap energy which is gradually decreased in a direction of the front electrode layer.

5. The solar cell apparatus of claim 3, wherein the light absorbing layer includes a bandgap control material, and
wherein a content of the bandgap control material in the first region is gradually increased in a direction of the front electrode layer,
a content of the bandgap control material in the second region is gradually decreased in a direction of the front electrode layer,
a content of the bandgap control material in the third region is gradually increased in a direction of the front electrode layer, and
a content of the bandgap control material in the fourth region is gradually decreased in a direction of the front electrode layer.

6. The solar cell apparatus of claim 5, wherein the bandgap control material is selected from sulfur, silver, gallium, and aluminum.

7. The solar cell apparatus of claim 1, wherein each thickness of the first to fourth regions is in a range of 20 nm to 40 nm.

8. The solar cell apparatus of claim 1, wherein the first region is defined at a middle portion of the light absorbing layer.

9. A solar cell apparatus comprising:
a substrate;
a back electrode layer on the substrate;
a light absorbing layer on the back electrode layer; and
a front electrode layer on the light absorbing layer,
wherein the light absorbing layer comprises:
a first region having a conduction band which is gradually increased in a direction of the front electrode;
a second region on the first region, the second region having a conduction band which is gradually decreased in a direction of the front electrode;
a third region on the second region, the third region having a conduction band which is gradually increased in a direction of the front electrode; and
a fourth region on the third region, the fourth region having a conduction band which is gradually decreased in a direction of the front electrode.

10. The solar cell apparatus of claim 9, wherein the light absorbing layer includes a group I-III-VI semiconductor compound, and
wherein a content of gallium in the first region is gradually increased in a direction of the front electrode layer,
a content of gallium in the second region is gradually decreased in a direction of the front electrode layer,
a content of gallium in the third region is gradually increased in a direction of the front electrode layer, and
a content of gallium in the fourth region is gradually decreased in a direction of the front electrode layer.

11. A method of fabricating a solar cell apparatus, the method comprising:
forming a back electrode layer on a substrate;
forming a light absorbing layer on the back electrode layer; and
forming a front electrode layer on the light absorbing layer,
wherein the light absorbing layer comprises:
a first region having a bandgap energy which is gradually increased in a direction of the front electrode;
a second region on the first region, the second region having a bandgap energy which is gradually decreased in a direction of the front electrode layer;
a third region on the second region, the third region having a bandgap energy which is gradually increased in a direction of the front electrode layer; and
a fourth region on the first region, the fourth region having a bandgap energy which is gradually decreased in a direction of the front electrode layer.

12. The method of claim 11, wherein the forming of the light absorbing layer includes:
forming a lower light absorbing layer on the back electrode layer; and
forming the first region by supplying group I, III and VI elements, and a bandgap control material onto the lower light absorbing layer,
wherein a rate of supplying the bandgap control material is gradually increased as the first region is formed.

13. The method of claim 12, wherein the forming of the light absorbing layer includes:
forming the second region by supplying the group I, III and VI elements, and the bandgap control material onto the first region,
wherein the rate of supplying the bandgap control material is gradually decreased as the second region is formed.

14. The method of claim 13, wherein a process temperature for forming the first and second regions is in a range of 400° C. to 460° C.

15. The solar cell apparatus of claim 1, wherein the light absorbing layer includes a harmonic region which has a bandgap energy of a harmonic shape.

16. The solar cell apparatus of claim 15, wherein the harmonic region is formed in an upper portion of the light absorbing layer.

17. The solar cell apparatus of claim 15, wherein the harmonic region includes the first region to the fourth region.

18. The solar cell apparatus of claim 9, wherein the light absorbing layer includes a harmonic region which has a conduction band of a harmonic shape.

19. The solar cell apparatus of claim 18, wherein the harmonic region is formed in an upper portion of the light absorbing layer.

20. The solar cell apparatus of claim 18, wherein the harmonic region includes the first region to the fourth region.
